(19) United States
(12) Patent Application Publication
(10) Pub. No.: US 2026/0320248 A1
(43) Pub. Date: Oct. 15, 2026

(54) SINGLE-PHASE VOLTAGE REGULATOR OPERATION SIMULATOR EQUIPMENT, CONTROL MODULE, AND SYSTEM FOR REGULATING DEVICE SIMULATION

(71) Applicant: TRANSFORMADORES E SERVIÇOS DE ENERGIA DAS AMÉRICAS S.A., Contagem - MG (BR)

(72) Inventor: Felipe Vilaça Marchezini, Contagem (BR)

(21) Appl. No.: 19/647,980

(22) Filed: Apr. 15, 2026

(30) Foreign Application Priority Data
Apr. 15, 2025 (BR) 1020250074630

(51) Int. Cl. G06F 30/20; H02J 3/00; H02J 103/30

(52) U.S. Cl. CPC G06F 30/20; H02J 3/00; H02J 2103/30

(57) ABSTRACT

The present invention relates to an operation simulator equipment of single-phase voltage regulators connected to electrical power distribution networks with automatic operation counter pulse generation and multi-phase capacity. The present invention can create a safe and controlled environment for testing and operating electronic controllers of voltage regulators, through a single equipment that reproduces the operation of a single-phase regulator transformer. The equipment is based on computer simulations of an electrical network, being able to respond to the control signals of the controller and emulate voltage, current signals and the automatic operation counter pulses of the single-phase voltage regulator transformers, among other functionalities. This equipment allows joint operation, for multiphase simulation, with communication between multiple emulators via CAN protocol, allowing advanced tests of regulators operating in bank for multiphase networks, connected in star, open and closed delta, with the controllers in modes of operation such as Master-Slave and Master-Follower. Thus, the invention provides for the validation and training of voltage regulator controllers, aiming for the electrical voltage of the network to remain within the pre-established limits, even under variable conditions of load, generation or impedance of the line.

### FIELD OF THE INVENTION

The present invention relates to equipment for simulating the operation of a single-phase voltage regulator device, capable of multi-phase operation, through a voltage emulator device, currents and functionalities of a single-phase voltage regulator transformer, based on command signals sent by an electronic controller to voltage regulators and computer simulations of this regulator device connected to an electrical power distribution line. The present invention is situated in the fields of electrical engineering, electrical power distribution networks, simulation and emulation technologies.

### BACKGROUND OF THE INVENTION

Voltage regulators of medium voltage are used in alternating current (AC) electrical power distribution systems, to measure, control and regulate the voltage of these networks, in the face of fluctuations in load and/or power supply, and regardless of the direction of power flow in the distribution line (direct or reverse). Single-phase voltage regulator transformers, as described in U.S. Pat. No. 2,677,810A, are used to replace three-phase regulators and aim to keep the voltage on the load in distribution lines at strategic points or in substations regulated. The voltage regulator transformer is basically an autotransformer with the ability to increase or decrease the voltage of the system by exchanging the physical connection (tap) between the windings, an exchange that is performed through an on-load tap changer.

The voltage regulator device has in a common electromagnetic core, a primary excitation winding, and a secondary regulation winding that is composed of a set of taps. The voltage variation is obtained by changing the position of the tap contact, through an on-load switching mechanism.

The automatic voltage regulation operation is performed using microprocessor electronic controls, as described in U.S. Pat. No. 4,419,619 A, which provide parameterization, data acquisition, analysis and control of the output voltage of the system. The main function of the Voltage Regulator Controller device, or Voltage Regulator Relay, is to determine the tap position of the tap changer mechanism of the single-phase voltage regulator transformer, aiming to keep the voltage at the consumer within selected limits, monitoring the parameters of the line and activating the on-load tap changer.

The proper operation of the voltage regulator is directly linked to the correct operation and parameterization of the Voltage Regulator Controller, in view of the various operating conditions of a distribution line. Thus, it is evident the importance of having a controlled environment for testing and operation of the Controller, especially due to the characteristics and risk of explosion of the voltage regulator device, which can result in death or personal injury to the operator and damage to equipment.

Tests and operations of the Voltage Regulator Controller undergo the interaction of this device with the voltages, currents and functionalities of a voltage regulator device, in the face of voltage variations of an electrical power distribution network. The variations may be caused by changes in the characteristics of the distribution network, load and/or generation fluctuations, and change in the direction of power flow in the distribution line.

In the search for the state of the art, the following documents dealing with the subject were found:

Documents such as CN104091482B, JP5444131B2 and CN111709107B deal with training and simulation systems for the operation and maintenance of electrical distribution networks: intelligent, with bidirectional power flow, and with large insertion of power electronic equipment, respectively. The solutions presented do not specifically address the interaction of these networks with the voltage regulator devices, nor are they capable of interacting with the functionalities of the regulator.

Documents such as U.S. Pat. Nos. 7,415,377B2 and 7,180,297B2 deal with programmable systems and devices for testing relays and control systems. The test devices include a plurality of fixedly or removably coupled generator components, and a CPU to promote test signal generation by the signal generator and an amplifier to amplify the signals generated by the signal generator. The solutions presented are generic and employed in the testing of protection relays, but despite emulating voltage and current signals, they do not specifically address the interaction of the distribution networks with the voltage regulator devices, nor are they capable of interacting with the functionalities of the regulator.

An alternative for testing and operation of the voltage regulator controller is the use of a pilot plant or a controlled microgrid, which can be scaled down, with one or more voltage regulator devices connected. This test system shall allow changing characteristics and impedances of the distribution network, load and generation fluctuations, and change in the direction of power flow in the distribution line where the voltage regulators are connected. This is a complex solution, as it simultaneously involves several elements of electrical distribution systems; it requires controllability of loads, generations and other network elements; high cost of purchasing, operating and maintaining the infrastructure; in addition to the necessary physical space. In addition, it offers the risks of on-load operation of voltage regulators and other system elements.

Thus, in view of the state of the art raised, no documents were found anticipating or suggesting the teachings of a system or device that: simulates the interaction of a voltage regulator with a distribution network, emulates the simulated electrical quantities and functionalities of a voltage regulator, and also communicates and interacts with a Voltage Regulator Controller, allowing the operation and testing of this controller, without having to connect a voltage regulator to a distribution line.

The present invention aims to provide a programmable system for testing a voltage regulator controller, through an emulator device of the signals of a single-phase voltage regulator, capable of multi-phase operation, connected to an electrical distribution network. The emulated signals, in turn, are based on results of dynamic simulations in the phasor domain, for different configurations or modes of operation of an electrical distribution network.

### BRIEF DESCRIPTION OF THE DRAWINGS

FIG. 1 illustrates a block diagram of the basic elements that make up a system for testing with the proposed equipment.

FIG. 2 illustrates an equivalent electrical circuit for a phase of a distribution line with a single-phase voltage regulator transformer.

FIG. 3 shows a connection schematic for polyphase bank operation employing two voltage regulator transformer emulators.

FIG. 4 shows a connection schematic for polyphase bank operation employing three voltage regulator transformer emulators.

### DESCRIPTION OF THE INVENTION

The present invention consists of equipment for simulating the operation of a single-phase voltage regulator connected to an electrical distribution network. The physical apparatus provides an interactive platform for testing and operation of electronic controllers for voltage regulators (12).

The simulation technique is based on an equipment capable of emulating all the signals produced by a single-phase voltage regulator transformer in operation, in a single-phase or multi-phase (bank) configuration. The emulated signals, in turn, are based on computer simulations of the distribution network to which the voltage regulators are used. In this way, in a fast, simple and safe way, it is possible to evaluate the control and operation of voltage regulating transformers in the face of changes in the characteristics of the distribution network, load and/or generation fluctuations, and change in the direction of power flow in the line.

FIG. 1 is a block diagram of the programmable system for testing a voltage regulator control equipment (12), through the emulator device of the signals of a voltage regulator (11) that operates connected to a power distribution line. The emulated signals reflect the results of simulations of an electrical distribution network, programmed via dedicated software, in an external device (13) that contains the application (PC, laptop, smartphone, tablet or similar).

The system presented in FIG. 1 provides a controlled and safe means for testing and operation of the microcontrolled electronic control for single-phase voltage regulators (12). The equipment (12) aims to keep the electrical voltage of the network within pre-established limits, by constantly monitoring the parameters of the distribution line and activating the on-load tap changer of the voltage regulator. Thus, the controller (12) provides parameterization, data acquisition, analysis and control of the output voltage of the system.

Currently, commercial controllers (12) usually employ cable harness for multichannel interconnection with voltage regulators in the transfer of control signals, measurement inputs, auxiliary circuits and power. Thus, the present invention employs a cable harness with quick-engaging sockets for the connection between the controller (12) and the equipment that simulates the operation of the voltage regulator (11).

The voltage regulator emulator device (11), which is a central part of this inventive concept represented in FIG. 1, is advanced equipment that simulates the operation of a single-phase voltage regulator connected to a distribution line, providing a validation and training platform for the controller (12). The emulator (11) can generate various signals including voltage, current, power flow, frequency, polarity inverter signal, operation counter pulse, neutral light and switch position sensor, and simulating the tap-changing mechanism by spring-loaded or direct drive switch.

For this purpose, the emulator device (11) is composed of a control module (111) and a power module (112).

The control module (111) based on the microcontroller is responsible for processing all analog and digital signals exchanged with the controller (12), establishing communication with the control software in an external device (13) and commanding the power module (112).

Thus, it is necessary to condition the analog input and output (I/O) AC signals connected to the controller (12), such as: on-load TAP changer activation signals in the direction of raising or lowering TAP, neutral position signals referenced to the neutral or to the phase, retention contact signal for switches with actuation system without spring loads. The AC input and output electronic submodule (1111) is used to condition and transfer the treated and protected signals between the controller (12) and the microcontrolled processing and control unit (1114).

Similarly, it is necessary to condition the input and output signals in direct current (DC) such as analog switching counter signal sent by the controller (12) and 3-position switch signal for phase programming (R, S or T) in bank operation. The DC I/O electronic submodule (1112) is used to condition and transfer the treated and protected signals between the controller (12) and the microcontrolled processing and control unit (1114).

There is also the conditioning of dry contact digital output signals to feed back the control (12), such as: neutral position indicator, operations counter, polarity inversion indication and auxiliary relays. The electronic dry contact output submodule (1113) is used in the conditioning, to then send the treated and protected signals to the controller (12).

The signaling panel (1115) is employed to visually indicate, by electronic display or light emitting diodes (LED), the status of some digital variables, such as: Switching operation count, polarity reversal indication and switch indication in neutral position.

Communication interfaces (1116) are used between the microcontroller (1114) and the computerized device (13) that has the emulator control software (11). For this purpose, serial communication standards are used in data transmission, with the customer having the option of a Universal Serial Bus (USB) port and an RS-232 port. In addition, the communication interface module (1116) also performs the integration between different emulators (11) that operate in bank. The interaction between the emulators (11) is based on the serial digital communication protocol Controller Area Network (CAN). In addition, terminals are used for measuring output voltage and current.

The microcontrolled processing and control unit (1114) is responsible for processing all input and output signals in the control module (111) and governing the flow of information and activities within the equipment (11). It executes the instructions stored in memory by performing mathematical calculations, manipulating data and making logical decisions, to determine which instructions will be executed at what time, coordinating the work of all other components of the system.

In short, the microcontroller (1114) receives the commands from the controller (12), sends to the device with emulator control software (13) that simulates the network conditions in the phasor domain for the selected TAP adjustment. The microcontroller (1114) receives the simulated voltage and current results and commands the power module (112) to reproduce them analogically in time.

The power module (112) is responsible for emulating current and voltage signals that would be measured during operation of a single-phase voltage regulator transformer. Thus, there is a submodule that reproduces the analog signals of the voltage measurement (1121) and a submodule that reproduces the analog signals of the current measurement (1122) of what would be the operation of the regulator. The reference is received from the microcontroller (1114) and the submodules (1121 and 1122), which include a plurality of components, promote the generation of the emulation signals through signal generators and amplifiers.

Still based on FIG. 1, the voltage regulator emulator (11) establishes connection with an external computerized device (13). This device (13), which can be a PC, laptop, smartphone, tablet or similar, as long as it has the emulator control application, exercises serial communication via USB or RS-232 with the emulator device (11).

Through the control software it is possible to configure the characteristics of the voltage regulator, as well as the characteristics of the simulated network. The application performs the simulation of the network in the phasor domain and returns the references to the emulator device (11) that reproduces the signals. The simulation routine performs the calculations and triggers the new reference values to the emulator (11) at each command action of the controller (12) or at each change of characteristic of the network or the voltage regulator.

The software also receives and indicates the state of binary signals such as Neutral Light, lowering TAP, Raising TAP etc. Receives and sends the values of analog variables such as Voltage, current and angle. It allows the updating of the emulator firmware (11).

The simulated distribution network may be, for example, an electrical network, a microgrid or an electrical system, which provides AC, single-phase or multi-phase electrical power, to commercial and/or residential customers. The network may operate at a fundamental frequency of, for example, 50 to 60 Hertz (Hz) and may have an operating voltage of, for example, at least 1 kilovolt (kV), up to 138 kV.

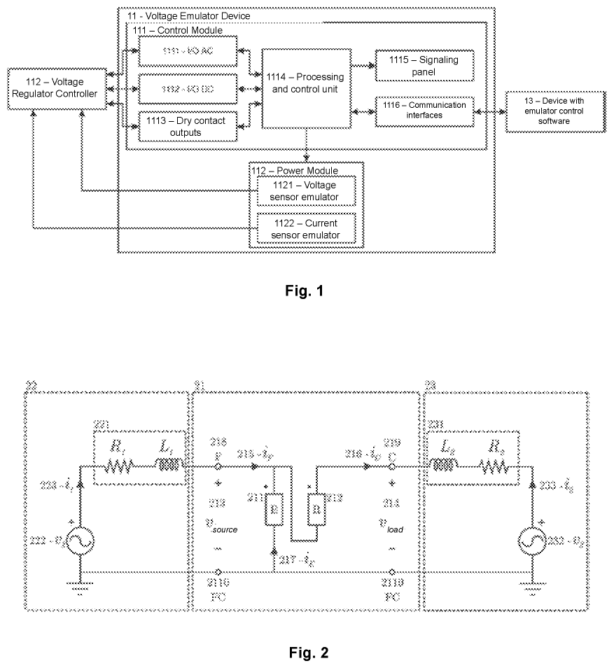

The system simulation, represented in FIG. 2 for a phase, consists of a distribution line with a single-phase voltage regulator (21). A representative model of the single-phase voltage regulator transformer (21) composed of an excitation winding (211) between the source terminals (218) and source-load (2110) and a regulation winding (212) connected between the source terminals (218) and load (219) is employed. The network model employed is a Thévenin equivalent circuit, composed of a voltage source in series with an impedance, which can produce an equivalent response to the entire system.

Thus, the entire distribution network downstream of the regulator (21) is represented by the Thévenin equivalent circuit (22) that has a voltage source (222) in series with a resistive inductive impedance (221). Similarly, the entire distribution network upstream of the regulator (21) is represented by the circuit (23) that has a voltage source (232) in series with a resistive inductive impedance (231).

The equivalent circuits (22 and 23) can represent a composition of one or more sources of electricity such as, for example, hydroelectric power plant, thermoelectric power plant, or electrical substation, and further one or more distributed energy resources such as, for example, photovoltaic or wind solar micro and mini-generation units. The representation also includes one or more distribution lines, electrical cables, and/or any other mechanism for transmitting electricity in addition to the electrical loads. Any device that uses electricity, including electrical equipment that receives and transfers or distributes electricity to other equipment in the distribution network are considered loads, for example, transformers, switchboards, energy storage systems, computers and communication equipment, lighting, air conditioning, motors and electrical machinery in an industrial facility, and/or household appliances and electrical systems in a residence.

It is known that the control for voltage regulator (12) acts to keep the voltage at the consumer within pre-established limits, monitoring the parameters of the line and activating the on-load tap changer of the voltage regulator transformer (21). Thus, through the simulation of the diagram presented in FIG. 2, it is possible to establish numerous boundary conditions for testing the control algorithm. Through the configurable circuits (22 and 23) it is possible to change the characteristics of the distribution network, force load and/or generation fluctuations, and change the direction of power flow in the distribution line.

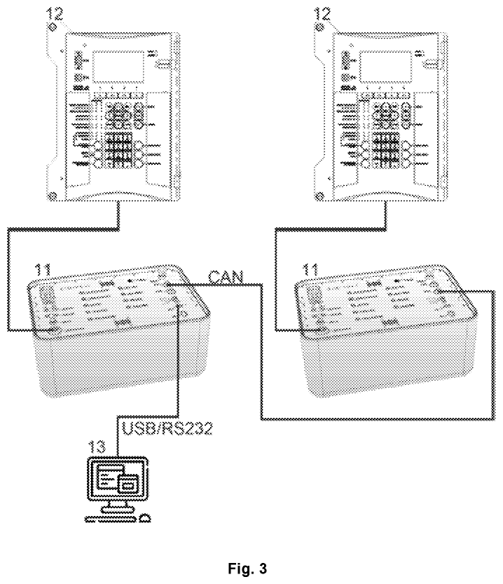

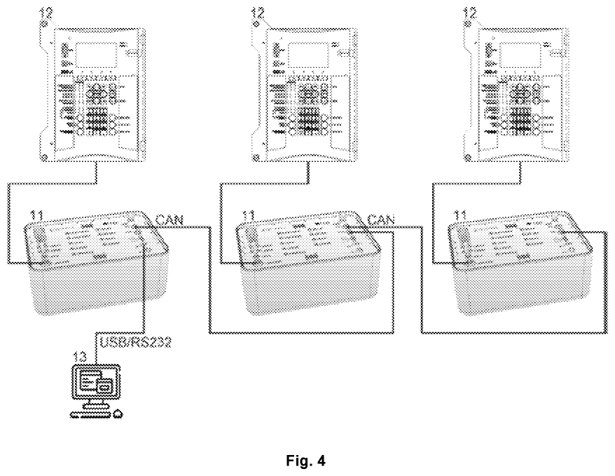

Although the systems presented so far (FIGS. 1 and 2) are single-phase, it is very common to use single-phase voltage regulator transformers in a bank for multi-phase operation. Thus, as indicated in FIGS. 3 and 4, the emulator device (11) is equipped with the ability to communicate with other compatible emulators, allowing the multiphase management of the simulation of the regulator banks and enabling the configuration of all interconnected equipment through a single computerized device with the control application (13).

FIG. 3 shows a connection schematic for bank operation of the present system, which, for example, could be the simulation of a three-phase line with two single-phase voltage regulators (21) connected in open delta, that is, a three-wire connection where one of the phases becomes the central connection point of the transformers, creating a pseudo-neutral with high impedance. Similarly, FIG. 4 shows a connection schematic for bank operation of the present system, which, for example, could be a three-phase line employing three single-phase voltage regulators connected in a closed star or delta. The CAN communication channel between the individual equipment (11) enables the command or change of the configuration of all interconnected equipment through a single control software (13), as well as centrally monitoring the measurements of all phases. Thus, it is possible to connect and communicate with one element of the emulator bank (11) at a time or to send commands to one or more emulators (11) of the bank at once.

It should be noted that for the bank operation exemplified in FIGS. 3 and 4, each single-phase voltage regulator has its own control (12). However, the simulation system presented can be used to test both single-phase control (12) and multi-phase control.

The Single-phase Control (12) is characterized by controlling only one single-phase voltage regulator transformer, in which each regulator transformer needs its own control. In a multi-phase electrical system, the Single-phase Control (12) always performs voltage regulation based on the measured electrical parameters of a single phase, the phase in which the voltage regulator is installed, disregarding the parameters of the other phases. The operation of regulating independently between the phases of a three-phase electrical system with unbalanced loads is inadequate in some situations. As a variation of the application of Single-phase Controls, some equipment allows operation in a slave master system where two or more single-phase controls (12) operate in position synchronization (taps). In this configuration, one of the controls becomes the master, the voltage regulation occurs according to the need to regulate the master control line, the other equipment is commanded to maintain the synchronism of positions (tap) between the controls. Voltage regulation occurs only according to the need to correct the voltage of the master control phase, disregarding the need to regulate the other phases.

The Multiphase Control is a microprocessed electronic equipment that is characterized by controlling up to three single-phase voltage regulator transformers, a single equipment can replace up to three Single-phase Controls (12), and it is not necessary that each transformer has its own control. It allows that in a three-phase electrical system the regulation is performed individually per phase or simultaneously in all phases. Voltage regulation can be performed by considering the measured electrical parameters in one or all phases.

Thus, the ability to interconnect the emulators (11) with others of the same type, allows not only to simulate the different types of connection of the regulators (21)—star, open delta and closed delta—but also to test systems with two or more controllers (12) to validate the modes of operation in Master-Slave and/or Master Follower bank.

### EXAMPLE

A clear example of embodiment of the invention is a commercial emulator (11) under development by the applicant, which has already gone through the stages of research, planning, prototyping and development and is in the patenting and improvement phase.

The electronic voltage regulator simulator equipment (11) is an advanced device that simulates a single-phase voltage regulator for distribution lines providing a validation and training platform for the control of regulators (12). It can generate various signals including voltage, current, power flow, frequency, polarity inverter signal, operation counter pulse, neutral light and position sensor, and simulating the tap-changing mechanism by spring-loaded or direct drive switch. In addition, through software (13), it is possible to view all levels of the signals, as well as to configure values and send commands in a friendly and intuitive way. The simulator (11) is also able to interconnect with others of the same type, allowing the simulation of a system with two or three regulators to validate the modes of operation in Master-Slave and/or Master Follower bank.

Many of the modifications and variations of the present patent application can be made without departing from its spirit and scope, as will be apparent to those skilled in the art.

The invention is defined by the terms of the appended claims and is not to be limited in scope by the specific embodiments described herein. Indeed, various modifications of the invention in addition to those shown and described herein will become apparent to those skilled in the art from the foregoing description and the accompanying FIGS. 1 to 4. Such modifications are intended to be within the scope of the appended claims.

The above written description is sufficient to enable a person skilled in the art to reproduce the invention without undue experimentation.

1. An OPERATION SIMULATOR EQUIPMENT (11) FOR A SINGLE-PHASE VOLTAGE REGULATOR DEVICE (12), in a single-phase or multi-phase configuration, comprising:
at least one control module (111); and
at least one power module (112).

2. The SIMULATOR EQUIPMENT (11) according to claim 1, wherein the control module (111) employs:
at least one input and output electronic submodule AC I/O (1111);
at least one input and output electronic submodule DC I/O (1112);
at least one electronic dry contact output submodule (1113);
at least one processing and control unit (1114);
signaling panel (1115); and
at least one communication interface (1116);
wherein the control module (111) processes all analog and digital signals exchanged with the single-phase voltage regulator device (12), establishes communication with a control software in an external device (13) and commands the power module (112).

3. The SIMULATOR EQUIPMENT (11) according to claim 1, wherein the power module (112) employs:
at least one voltage sensor emulator (1121); and—at least one current sensor emulator (1122); wherein the power module (112) emulates current and voltage signals that would be measured during operation of the single-phase voltage regulator device (12).

4. The SIMULATOR EQUIPMENT (11) according to claim 1, wherein it simulates the functionalities of a single-phase voltage regulator device (12), based on command signals sent by an electronic controller to voltage regulators and computer simulations of the regulator device (12) connected to an electrical power distribution line.

5. The SIMULATOR EQUIPMENT (11) according to claim 4, wherein the functionalities of the simulated single-phase voltage regulator device (12) are chosen from voltage and current.

6. The SIMULATOR EQUIPMENT (11) according to claim 1, wherein it has the capacity to:
generate at least one signal from among the signals of the group consisting of: voltage, current, power flow, frequency, polarity inverter signal, operation counter pulse, neutral light and switch position sensor; and
simulate the tap-changing mechanism by spring-loaded or direct drive switch and comprising:
RS-232 and USB serial local ports for communication with external computerized device (13) with the equipment control software (11);
CAN communication ports for bank operation with other compatible single-phase voltage regulator device simulator equipment (11);
terminals for measuring output voltage and current;
switches for manual selection of the phase (R, S or T) and the electrical voltage of the tap-changing mechanism motor (110 Vac or 220 Vac);
signaling panel (1115) to visually indicate, by electronic display or light emitting diodes (LED), the status of some digital variables;
a power module (112) that includes a plurality of electronic components that promote the generation of the signals through signal generators and amplifiers, and can emulate voltage and current in alternating current (AC) equivalent to those produced by sensors of single-phase voltage regulator transformers;
a microcontroller-based control module that includes a plurality of electronic components that promote the processing of all analog and digital signals, AC or direct current (DC), exchanged with the Electronic Control for Voltage Regulators, establish communication with the control software in an External Computerized Device, and produce reference signals for the power module.

7. A CONTROL MODULE (111), comprising:
an AC Input and Output Sub-module that includes a plurality of electronic components that promote the conditioning and transfer of the treated and protected AC signals (such as on-load tap changer activation signals in the direction of raising or lowering TAP, neutral position signals referenced to the neutral or to the phase, retention contact signal for switches with actuation system without spring loads) between the Electronic Controller for Voltage Regulators and the Microcontrolled Processing and Control Unit;
a DC Input and Output Sub-module that includes a plurality of electronic components that promote the conditioning and transfer of the treated and protected DC signals (such as analog switching counter signal sent by the Electronic Controller for Voltage Regulators and 3-position switch signal for phase programming—R, S or T—in bank operation) between the Electronic Controller for Voltage Regulators and the Microcontrolled Processing and Control Unit;
a Dry Contact Output Sub-module that includes a plurality of electronic components that promote the conditioning and transfer of the treated and protected digital relay signals (such as neutral position indicator, operations counter, polarity inversion indication and auxiliary relays) to the Electronic Controller for Voltage Regulators;
a Signaling Panel (1115) that includes a plurality of electronic components that promote the visual indication, by electronic display or light emitting diodes (LED), the status of some digital variables, such as: Switching operation count, polarity reversal indication and switch indication in neutral position;
a Communication Interfaces Sub-module that includes a plurality of electronic components that promote communication between the equipment and the External Computerized Device through serial communication standards in data transmission (RS-232 and USB), and between compatible equipment operating in bank, via serial digital communication protocol Controller Area Network (CAN); and
a Processing and Control Sub-module that includes a microcontroller and a plurality of electronic components that promote the processing of all input and output signals in the CONTROL MODULE and govern the flow of information and activities within the equipment, executing the instructions stored in memory by performing mathematical calculations, manipulating data and making logical decisions, to determine which instructions will be executed at what time, coordinating the work of all other components of the system in which the control module (111) is comprised in a simulator equipment (11) of operation of a single-phase voltage regulator device (12), according to claim 1.

8. A SYSTEM FOR SIMULATING A SINGLE-PHASE VOLTAGE REGULATOR DEVICE (12), comprising:
a single-phase voltage regulator device (12), which is an equipment that aims to keep the electrical voltage of the network within pre-established limits, by constantly monitoring the parameters of the distribution line and activating the on-load tap changer of the voltage regulator transformer, providing parameterization, data acquisition, analysis and control of the output voltage of the system;
a simulator equipment (11) of a single-phase voltage regulator device (12) according to claim 1, operably associated therewith;
an external computerized device (13) that exercises serial communication with the simulator equipment of a single-phase voltage regulator device and through the control software it is possible to configure the characteristics of the voltage regulator, as well as the characteristics of the simulated network, and then the application performs the simulation of the network in the phasor domain and returns the references to the equipment that reproduces the signals, the simulation routine performs the calculations and triggers the new reference values to the equipment at each command action of the electronic controller for voltage regulators or at each change of characteristic of the network or the voltage regulator; where the equipment receives the commands from the electronic controller for voltage regulators, it sends to the control software that simulates the conditions of the network in the phasor domain for the selected tap adjustment, and when the equipment receives the simulated voltage and current results, it reproduces all the control and power signals corresponding to the operation of a single-phase voltage regulator transformer.
